(19) United States
(12) Patent Application Publication
(10) Pub. No.: US 2026/0068642 A1
(43) Pub. Date: Mar. 5, 2026

(54) CIRCUIT FOR HIGH VOLTAGE IN SEMICONDUCTOR DEVICES

(71) Applicant: INTERNATIONAL BUSINESS MACHINES CORPORATION, Armonk, NY (US)

(72) Inventors: Baozhen Li, South Burlington, VT (US); Atsushi Ogino, Fishkill, NY (US); Matthew Stephen Angyal, Stormville, NY (US)

(21) Appl. No.: 18/825,580

(22) Filed: Sep. 5, 2024

(51) Int. Cl. H01L 23/528; H01L 23/522

(52) U.S. Cl. CPC H01L 23/5283

(57) ABSTRACT

A semiconductor device includes a high voltage electrode. A high voltage column is connected to the high voltage electrode. The high voltage column includes stacked metal structures layered to provide a vertical wire having a longitudinal axis substantially perpendicular with a stacking direction of the stacked metal structures.

### BACKGROUND

The present invention generally relates to semiconductor devices and processing methods, and more particularly to semiconductor structures with high voltage lines with reduced risk of interlayer breakdown.

With the new technology scaling, via height becomes shorter, and caping layers get thinner. A net effect of this is that spacings between metal line layers reach a threshold where an inter-level time-dependent dielectric breakdown (TDDB) between layers becomes a limiting factor for high voltage applications.

As a result, foundries prohibit high voltage input/output (I/O) circuits in most advanced technologies. For high performance computing, high voltage I/O is still needed. Therefore, a need exists for incorporating high voltage conductors in semiconductor devices.

### SUMMARY

In accordance with an embodiment of the present invention, a semiconductor device includes a high voltage electrode to carry a voltage greater than other metal structures on the semiconductor device. A high voltage column is connected to the high voltage electrode. The high voltage column includes stacked metal structures layered to provide a vertical wire having a longitudinal axis substantially perpendicular with a stacking direction of the stacked metal structures.

In other embodiments, the stacked metal structures can include a combination of vias and metal lines. The combination of vias and metal lines can include an alternating arrangement between the vias and the metal lines. The stacked metal structures can include a super via. The stacked metal structures can include array vias. The high voltage column can include a dielectric column that is free of other metal structures and surrounds the stacked metal structures.

In accordance with another embodiment of the present invention, a semiconductor device includes a backside power distribution network including a high voltage electrode to carry a voltage greater than other metal structures on the semiconductor device. A high voltage column is connected to the high voltage electrode. The high voltage column traverses a region of lower voltage metal structures in the backside power distribution network and includes stacked metal structures layered to provide a vertical wire having a longitudinal axis substantially perpendicular with a stacking direction of the stacked metal structures.

In other embodiments, the stacked metal structures can include a combination of vias and metal lines. The combination of vias and metal lines can include an alternating arrangement between the vias and the metal lines. The stacked metal structures can include a super via. The stacked metal structures can include array vias. The high voltage column can include a dielectric column that is free of other metal structures and surrounds the stacked metal structures.

In accordance with another embodiment of the present invention, a semiconductor device includes a high voltage electrode to carry a voltage greater than other metal structures on the semiconductor device. A high voltage column is connected to the high voltage electrode and includes stacked metal structures layered to provide a vertical wire disposed over the high voltage electrode and having a longitudinal axis substantially perpendicular with a stacking direction of the stacked metal structures, the stacked metal structures including vias and metal lines stacked in an alternating arrangement.

In other embodiments, the stacked metal structures can include a super via. The stacked metal structures can include array vias. The high voltage column can include a dielectric column that is free of other metal structures and surrounds the stacked metal structures.

In accordance with another embodiment of the present invention, a semiconductor device includes a high voltage electrode to carry a voltage greater than other metal structures on the semiconductor device. A high voltage column is connected to the high voltage electrode. The high voltage column includes stacked metal structures layered to provide a vertical wire having a longitudinal axis substantially perpendicular with a stacking direction of the stacked metal structures and a dielectric column that is free of other metal structures and surrounds the stacked metal structures.

In other embodiments, the stacked metal structures can include a combination of vias and metal lines. The combination of vias and metal lines can include an alternating arrangement between the vias and the metal lines. The stacked metal structures can include a super via. The stacked metal structures can include array vias.

In accordance with another embodiment of the present invention, a semiconductor device includes a backside power distribution network including a high voltage electrode to carry a voltage greater than other metal structures on the semiconductor device. A high voltage column is connected to the high voltage electrode. The high voltage column traverses the backside power distribution network and includes stacked metal structures layered to provide a vertical wire disposed over the high voltage electrode and having a longitudinal axis substantially perpendicular with a stacking direction of the stacked metal structures, the stacked metal structures include a combination of vias and metal lines; and a dielectric column that is free of other metal structures and surrounds the stacked metal structures.

In other embodiments, the combination of vias and metal lines can include an alternating arrangement between the vias and the metal lines. The stacked metal structures can include a super via. The stacked metal structures can include array vias.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows a cross-sectional view of a metal structure for a semiconductor device showing vertical wires formed from stacked vias and metal lines for carrying high voltage across a region of a device (e.g., high voltage input/output (I/O) circuit), in accordance with an embodiment of the present invention;

FIG. 2 shows a cross-sectional view of the metal structure for the semiconductor device of FIG. 1 showing a vertical wire formed from stacked vias and metal lines for carrying high voltage across a region, in accordance with an embodiment of the present invention;

FIG. 3 shows a cross-sectional view of a high voltage column including a super via among the metal structures forming the vertical wires for carrying high voltage across a region, in accordance with an embodiment of the present invention; and

FIG. 4 shows a cross-sectional view of a high voltage column including a via array among the metal structures forming the vertical wires for carrying high voltage across a region, in accordance with an embodiment of the present invention.

### DETAILED DESCRIPTION

In accordance with embodiments of the present invention, devices and methods are described which include high voltage columns using vertical stacks of vias and metal lines through a thickness of a semiconductor device. In an embodiment, high voltage circuit connections are provided without running into heightened reliability risks of interlevel dielectric breakdown. In an embodiment, high voltage connections are carried across regions of metal line layers through vertical paths instead of horizontal paths. The vertical paths or columns are confined to particular regions, e.g., over or below electrodes that interface with off-chip electrical connections. These particular regions limit areas where high voltage needs to be and eliminate high voltage lines from areas where high voltage is not needed.

In an embodiment, the high voltage connections are arranged vertically in the form of stacked vias and metal lines where the stacked vias and metal lines run generally in a vertical direction. The vertically disposed high voltage column(s) limit places on a chip where high voltage needs to be routed, this can relax pitches between metal layers and in between metal structures within a same metal layer. With shrinking node size, tighter pitches and tighter gap distances are needed to permit smaller sized devices. By relaxing these distances, higher reliability can be achieved, especially for high voltage structures.

High voltage wiring also creates concerns for dielectric breakdown. Time-dependent dielectric breakdown (TDDB) is a measure of device wear out, a failure mechanism that results from a breakdown of materials over time. Breakdowns can occur as a result of long-time application of relatively low electric fields or can break down over shorter periods (or immediately breakdown) under higher voltage stress. The breakdown is caused by the formation of a conducting path through the dielectric. By ensuring a larger thickness of dielectric the TDDB reliability can be increased.

Relaxed pitch can be employed to increase interlevel TDDB reliability and intra-level TDDB reliability. For example, intra-level TDDB is relaxed when a spacing between structures within a same metal line is increased (relaxed) to accommodate high voltage connections. In this way, TDDB becomes less of a concern in high voltage applications as limitations to dielectric thicknesses are relaxed. Depending on use voltage, different stack via heights can be selected for different voltage domains. The via stack height provides a distance between horizontal metal layers, so increased height is needed for higher voltages.

High voltage columns in accordance with embodiments of the present invention can include single vias, stacked vias, via arrays or combinations of these and other metal structures. In some embodiments, a skip via or super via can be employed to fabricate the high voltage column. In other embodiments, vias can be stacked from a frontside and a backside of the device. In still other embodiments, the high voltage columns can include staged columns where a column is transferred to a different area of a chip and then continues on a vertical path that is not collinear with a first vertical path of the high voltage column. For insulation resistance (IR) drop concerns, larger vias or array vias may be employed for vertical stacks or high voltage columns.

Stacked via structures carrying high voltage can be reserved for designated portions of a design in, for example, a backside power distribution network (BSPDN). In an embodiment, high voltage columns can extend between back end of the line (BEOL) structurers on a frontside and the backside power distribution network (BSPDN) or backside interconnect metallization layer on the backside.

In another aspect, horizontal wiring may not be feasible at lower tight pitch metal levels due to smaller vertical spacing. Here, horizontal spacing can be relaxed by design, however, vertical spacing is fixed. The high voltage columns can be employed to bridge from fixed vertical spacings to regions (e.g., upper metal levels) that can have relaxed pitch levels to enable horizontal wiring, where both vertical and horizontal spacings are relaxed.

In some embodiments, portions of the high voltage columns can be formed in different process steps to enable different thicknesses and types of metal materials and sizes for stacked structures. In addition, different conductive materials can be employed for different portions of the stacked structures.

Embodiments of the present invention can be applied to any device types including but not limited to fin devices, forksheet devices, stacked field effect transistor devices, input/output devices, etc.

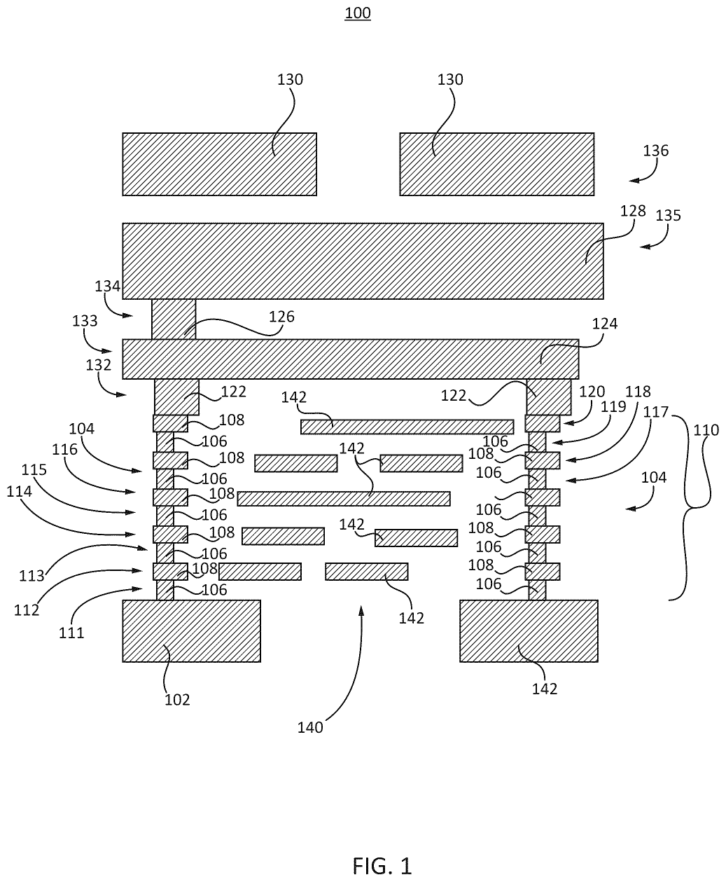

Referring now to the drawings in which like-numerals represent the same or similar elements and initially to FIG. 1, a cross-sectional view of a semiconductor device 100, such as, e.g., an I/O device, having multiple layers of metal lines is shown in accordance with embodiments of the present invention. The semiconductor device 100 depicted in FIG. 1 shows a portion of a metal structure. A semiconductor device is usually formed on a wafer that includes a substrate on which field effect transistor (FET) devices are fabricated. FIG. 1 depicts a cross-sectional view that cuts through layers of metal structures. Dielectric materials between the metal structures have been omitted for clarity.

Dielectric materials surround the metal structures. The dielectric materials rely on their properties and amounts (thicknesses) to prevent voltage breakdowns between adjacent metal structures. In particularly useful embodiments, dielectric materials, which can include interlayer dielectric (ILD) layers can be deposited over the wafer. The dielectric materials can include any suitable material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric materials can be deposited using chemical vapor deposition (CVD), although other deposition methods can be employed. The dielectric materials in each layer can be planarized, e.g., by chemical mechanical polishing (CMP), to level off a free surface.

In some embodiments, the free surface is then patterned for a next metal layer (e.g., for metal lines or vias, as needed). For example, a dielectric layer can be patterned by forming an etch mask and etching (e.g., by reactive ion etching (RIE)) openings in the dielectric layer. The patterning of the dielectric layer will depend on the metal structures to be formed. For example, if metal lines are to be fabricated then, metal line trenches are etched, if vias are to be fabricated then via openings are etched. In some embodiments, metal lines and vias can be formed in a dual damascene process.

After forming trenches and/or openings, a conductive fill is performed to make connections with other metal structures, to diffusion regions and/or to other electrodes as needed. Prior to the conductive fill, a diffusion barrier (not shown) can be formed. The diffusion barrier can include, e.g., TiN, TaN, or similar materials. The diffusion barrier can be deposited in the trench or opening (e.g., by atomic layer deposition (ALD)). Then, the conductive fill can be implemented. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), ALD, electrochemical plating or any other suitable deposition method. The conductive fill is planarized, e.g., by CMP, to form metal lines, vias, or other metal structures.

In other embodiments, rather than forming a dielectric layer and depositing conductive material in a patterned trench or opening, a layer of conductive material can be deposited and then subtractively etched to form metal lines and/or vias. It should be understood that any method can be employed to form metal lines and vias in accordance with embodiments of the present invention. In some embodiments, different processing methods can be employed in a same processing sequence for a same device.

In an illustrative embodiment, a frontside or backside power distribution network (BSPDN) includes power lines or power electrodes 102 that supply high voltage power to circuits on the device 100. In one example, high voltages can include voltages above 2.5 volts DC and can include voltages of up to and including 3000 VDC. The term “high voltage” is relative to the interconnect stack dimensions. For example, for frontside tight pitch metal/via levels, 2.5V can be high to run metal lines horizontally. The high voltage columns 104 can be employed to avoid tight pitch metal lines (e.g., in region 140) and carry this voltage until it can be distributed horizontally at upper metal layers where, at relaxed pitch levels, 2.5V is not high for TDDB concerns. At the relaxed pitch levels, 2.5V or higher can be easily handled at the relaxed pitch levels for both frontside and backside metal wires of the device without spatial limitations.

Vias 106 or contacts are formed in a first metal level 111 to connect to the electrodes 102. Then, a second metal level 112 is formed and patterned. The metal level 112 includes metal lines 108, which will form a portion of a high voltage column 104 and portions of metal lines 142 in region 140, which are not part of the high voltage column 104. The portions of metal lines 142 in region 140 are isolated from the high voltage columns 104 and are therefore isolated (by physical distance) from the high voltage carried by the high voltage columns 104. The portions of metal lines 142 in region 140 can include lower or normal voltage power lines or signal lines depending on a design of the device. In an embodiment, the portions of metal lines 142 in region 140 are part of a BSPDN and the high voltage columns 104 traverse the BSPDN. The high voltage columns 104 bridge high voltage power across the region 140. The high voltage columns 104 can be directly over the high voltage electrodes 102 (e.g., a vertical wire formed by the high voltage columns 104 is laterally positioned within a footprint of the high voltage electrodes 102).

Vias 106 or contacts are formed in a third metal level 113, a fifth metal level 115, a seventh metal level 117 and a ninth metal level 119 between a fourth metal level 114, sixth metal level 116, eighth metal level 118, tenth metal level 120. Successive layers of dielectric materials are formed followed by patterning and conductive fills to provide alternating layers of vias and metal lines. Although depicted as an alternating pattern, other configurations are contemplated, e.g., double vias, doubled metal lines, etc.

The vias 106 and the metal lines 108 in each layer contribute to the formation of the high voltage columns 104. Portions of metal lines 142 are concurrently formed with the metal lines 108 at each metal layer 112-120. Vias 106 can also be formed with vias (not shown) in the region 140. The metal level 112 includes metal lines 108, which will form a portion of a high voltage column 104 and portions of a metal line 142 which are not part of the high voltage column 104.

It should be understood that while a certain number of metal layers are illustratively described, any number of metal layers can be employed in greater or lesser numbers. It should also be understood that while an alternating pattern between metal lines and vias is described, multiple via layers and/or multiple metal lines layers can be employed adjacent to one another.

The high voltage columns 104 connect to high voltage connections 122, which, in turn, connect to local power lines 124 and/or global power lines 128 (through connection 126). Other conductive features 130 can include other voltages or structures connected to different high voltage columns 104. The high voltage columns 104 shown carry a same or different high voltage. In other embodiments, different voltages can be carried by different the high voltage columns 104. High voltages are limited to the high voltage columns 104 and the portion of metal lines 142 in the region 140 are not high voltage conductors.

The high voltage columns 104 carry high voltage across metal structures for a region 110 of a BSPDN. The design structure enables high voltage design for new technologies without increasing reliability risks, e.g., TDDB reliability risks or short circuiting due to proximity to high voltage conductors. Better wiring flexibility is also provided near the high voltage circuits. For example, there is no longer a need to block out wiring under, near or above high voltage wires. In this way, the design of metal structures in region 140 can remain unaffected by high voltage structures.

In another aspect, horizontal wiring across region 140 may not be feasible due to size constraints (tight pitch) of lower metal levels, e.g., levels 111-120, as a result of smaller vertical spacing. Here, horizontal spacing can be relaxed by design, however, vertical spacing is fixed. The high voltage columns 104 can be employed to bridge from fixed vertical spacings between levels 112-120 (with tight constraints) to relaxed vertical spacings for upper metal levels (e.g., metal levels 132-136) that can have relaxed pitch levels to enable horizontal wiring between high voltage electrodes, where both vertical and horizontal spacings are relaxed.

In an embodiment, high voltage connections 122 are taller than metal levels 111-120, and power lines 124 are thicker than the metal lines 142. High voltage connections 122 and power lines 124 of the upper metal levels have a relaxed pitch level to enable thicker lines. In this example, no horizontal wiring extends across the region 140 until power lines 124 are reached. At the lower levels 111-120, inter-level spacing is too small for high voltage, so no horizontal wiring is employed for a high voltage net. The high voltage columns 104 are employed to connect to the relaxed pitch, larger inter-level spacing levels (e.g., levels of high voltage connections 122 and power lines 124) for horizontal wiring for the high voltage net.

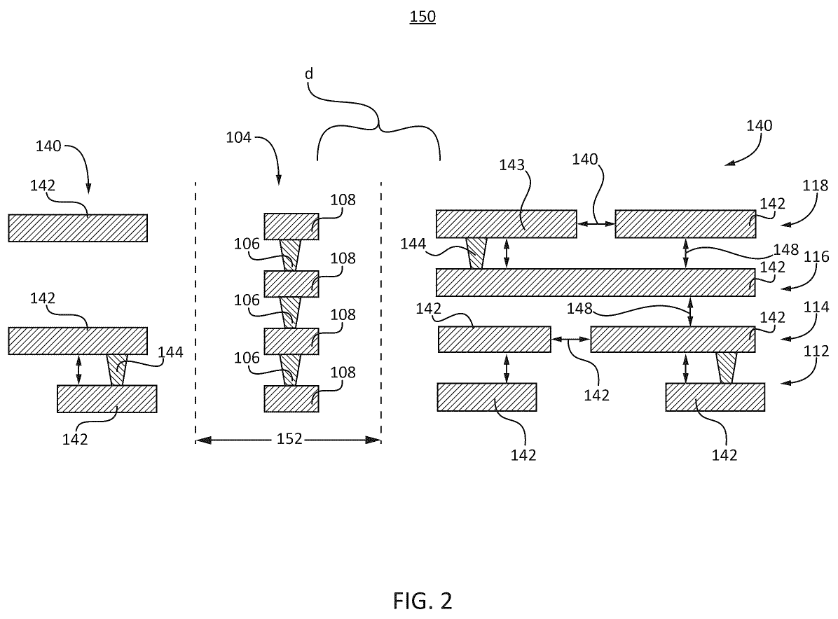

Referring to FIG. 2, a cross-sectional view of an illustrative metal structure 150 is shown in accordance with embodiments of the present invention. By including high voltage columns 104 in a metal structure design, intra-level spacings 146 between metal features in a same metal level can be relaxed. Relaxed means greater margins are enabled. With shrinking device sizes, scaling of via height and metal line sizes have a net effect of reaching a threshold where TDDB becomes a limiting factor for high voltage applications. To avoid this result, high voltage columns 104 are included to isolate high voltage lines from other structures to reduce the reliability risk of interlevel and intra-level dielectric breakdown.

If a metal line 142 at metal level 116 were to include high voltage, interlevel spacings 148 would need to increase to prevent breakdowns. In addition, if the metal line 142 at metal level 118 were to include high voltage, and metal line 143 did not include a high voltage, intra-level spacing 146 would need to increase to prevent a breakdown. By localizing the high voltage connections to designated areas, conductors in other areas no longer need to accommodate the high voltages. This permits the intra-level spacings 146 and the interlevel spacings 148 in region 140 to be closer with significantly less concern about breakdown issues.

Rather than running high voltage connections using metal line levels in a horizontal direction, stacked vias (high voltage columns 104) are employed to run via and metal line stacks vertically to relax pitch levels where the TDDB reliability is much higher. In region 140, metal structures (metal lines 142, 143, vias 144, etc.) can be set back an appropriate distance (d) from the high voltage columns 104 to ensure adequate dielectric material between the high voltage columns 104 and the metal structures.

By confining the high voltage dielectric distance (d) between the high voltage columns 104 and the metal structures in region 140, additional space is provided for the metal structures. For example, if a horizontal metal line carried high voltage than a metal layer above and below would need to be further separated from the high voltage horizontal metal lines. If additional high voltage horizontal metal lines are needed, these dimensions would stack up. If high voltage vias passed through region 140 at intermittent locations, theses vias would need to be further separated from other intra-level vias and metal lines. These dimensions would also stack and be costly in terms of layout real estate.

The high voltage columns 104 can be disposed within a dielectric column 152 that surrounds the high voltage columns 104. The dielectric column 152 can include sufficient distance from other metal structures (depending on the magnitude of the high voltage and the capabilities of the dielectric material). The dielectric column 152 is free of any metal structures that are not high voltage metal structures compatible with the high voltage columns 104. For example, low voltage metal structures are maintained a distance d away from the high voltage columns 104. Note that dielectric material also extends beyond the dielectric column 152.

In some embodiments, high voltage connections can be made to the high voltage columns 104 in both inter-level and intra-level directions. For example, a metal line can connect to a lateral side of the high voltage columns 104, and the high voltage columns 104 can connect to upper or lower metal lines, as needed. It should be understood that the high voltage columns 104 can be disposed at edges of the device but also can be more centrally located. The number and positions of the high voltage columns 104 can be a design choice and will depend on the type of device and its requirements.

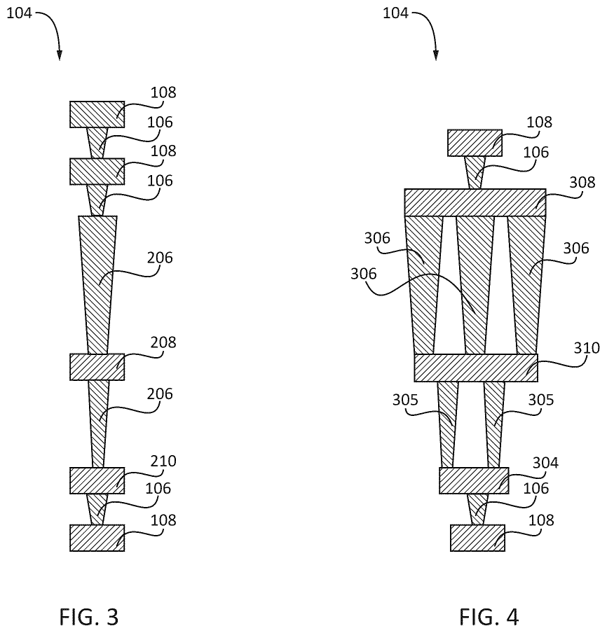

Referring to FIG. 3, a high voltage column 104 is shown having one or more super vias 206. A super via, also known as a skip via, can be formed through many dielectric layers. A super via can bypass one or more wiring structures within the dielectric layers to connect between an upper wiring structure 208 and a lower wiring structure 210. The super via 206 can provide improved resistance characteristics and can reduce capacitance. The super via 206 can be formed by etching through multiple layers of dielectric materials to expose the underlying wiring structure 210.

Prior to the conductive fill, a diffusion barrier (not shown) can be formed. The diffusion barrier can include, e.g., TiN, TaN, or similar materials. The diffusion barrier can be deposited in the trench or opening (e.g., by atomic layer deposition (ALD)). Then, the conductive fill can be implemented. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD, electrochemical plating or any other suitable deposition method. The conductive fill is planarized, e.g., by CMP, to form the super vias 206 or other metal structures.

Due to the tapered shape of the super via 206, a size of the super via 206 at an interface with the lower wiring structure 210 needs to be adequate. This can impact the depth to which the super via 206 can extend. In an embodiment, multiple super vias 206 can be stacked. The super vias 206 can include landing structures in between them or include a direct contact between the super vias 206.

Referring to FIG. 4, another high voltage column 104 is shown having one or more array vias 306. An array via includes multiple vias on a same metal level and can be formed through a single dielectric layer or many dielectric layers. The array via 306 connects between an upper wiring structure 308 and a lower wiring structure 310. The array via 306 can also provide improved resistance characteristics and can reduce capacitance. The array via 306 can be formed by etching a pattern through on or more layers of dielectric material to expose the underlying wiring structure 310.

Prior to the conductive fill, a diffusion barrier (not shown) can be formed. The diffusion barrier can include, e.g., TiN, TaN, or similar materials. The diffusion barrier can be deposited in the trench or opening (e.g., by atomic layer deposition (ALD)). Then, the conductive fill can be implemented. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD, electrochemical plating or any other suitable deposition method. The conductive fill is planarized, e.g., by CMP, to form array vias 306 or other metal structures.

In an embodiment, multiple array vias 306, 305 can be stacked. The array vias 306, 305 can include landing structures 310, 304 in between them or include a direct contact between the array vias 306, 305 on different levels. While a linear array of vias 306 is depicted (vias in a row), a two-dimensional array of vias is also contemplated.

It should be understood that while the present embodiments have been described in terms of metallization structures for a backside power distribution network (BSPDN) or backside interconnect metallization layer, the present embodiments are also applicable to frontside metal structures and can be formed to make connections to devices from a backside and/or a frontside of the device.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a high voltage electrode to carry a voltage greater than other metal structures on the semiconductor device; and
a high voltage column connected to the high voltage electrode, the high voltage column including:
stacked metal structures layered to provide a vertical wire having a longitudinal axis substantially perpendicular with a stacking direction of the stacked metal structures.

2. The semiconductor device as recited in claim 1, wherein the stacked metal structures include a combination of vias and metal lines.

3. The semiconductor device as recited in claim 2, wherein the combination of vias and metal lines include an alternating arrangement between the vias and the metal lines.

4. The semiconductor device as recited in claim 1, wherein the stacked metal structures include a super via.

5. The semiconductor device as recited in claim 1, wherein the stacked metal structures include array vias.

6. The semiconductor device as recited in claim 1, wherein the high voltage column includes a dielectric column that is free of other metal structures and surrounds the stacked metal structures.

7. A semiconductor device, comprising:
a backside power distribution network including a high voltage electrode to carry a voltage greater than other metal structures on the semiconductor device; and
a high voltage column connected to the high voltage electrode, the high voltage column traversing a region of lower voltage metal structures in the backside power distribution network and including:
stacked metal structures layered to provide a vertical wire having a longitudinal axis substantially perpendicular with a stacking direction of the stacked metal structures.

8. The semiconductor device as recited in claim 7, wherein the stacked metal structures include a combination of vias and metal lines.

9. The semiconductor device as recited in claim 8, wherein the combination of vias and metal lines include an alternating arrangement between the vias and the metal lines.

10. The semiconductor device as recited in claim 7, wherein the stacked metal structures include a super via.

11. The semiconductor device as recited in claim 7, wherein the stacked metal structures include array vias.

12. The semiconductor device as recited in claim 7, wherein the high voltage column includes a dielectric column that is free of other metal structures and surrounds the stacked metal structures.

13. A semiconductor device, comprising:
a high voltage electrode to carry a voltage greater than other metal structures on the semiconductor device; and
a high voltage column connected to the high voltage electrode, including:
stacked metal structures layered to provide a vertical wire disposed over the high voltage electrode and having a longitudinal axis substantially perpendicular with a stacking direction of the stacked metal structures, the stacked metal structures including vias and metal lines stacked in an alternating arrangement.

14. The semiconductor device as recited in claim 13, wherein the stacked metal structures include a super via.

15. The semiconductor device as recited in claim 13, wherein the stacked metal structures include array vias.

16. The semiconductor device as recited in claim 13, wherein the high voltage column includes a dielectric column that is free of other metal structures and surrounds the stacked metal structures.

17. A semiconductor device, comprising:
a high voltage electrode to carry a voltage greater than other metal structures on the semiconductor device; and
a high voltage column connected to the high voltage electrode, the high voltage column including:
stacked metal structures layered to provide a vertical wire having a longitudinal axis substantially perpendicular with a stacking direction of the stacked metal structures; and
a dielectric column that is free of other metal structures and surrounds the stacked metal structures.

18. The semiconductor device as recited in claim 17, wherein the stacked metal structures include a combination of vias and metal lines.

19. The semiconductor device as recited in claim 18, wherein the combination of vias and metal lines include an alternating arrangement between the vias and the metal lines.

20. The semiconductor device as recited in claim 17, wherein the stacked metal structures include a super via.

21. The semiconductor device as recited in claim 17, wherein the stacked metal structures include array vias.

22. A semiconductor device, comprising:
a backside power distribution network including a high voltage electrode to carry a voltage greater than other metal structures on the semiconductor device; and
a high voltage column connected to the high voltage electrode, the high voltage column traversing the backside power distribution network and including:
stacked metal structures layered to provide a vertical wire disposed over the high voltage electrode and having a longitudinal axis substantially perpendicular with a stacking direction of the stacked metal structures, the stacked metal structures include a combination of vias and metal lines; and
a dielectric column that is free of other metal structures and surrounds the stacked metal structures.

23. The semiconductor device as recited in claim 22, wherein the combination of vias and metal lines include an alternating arrangement between the vias and the metal lines.

24. The semiconductor device as recited in claim 22, wherein the stacked metal structures include a super via.

25. The semiconductor device as recited in claim 22, wherein the stacked metal structures include array vias.
